(19) United States
(12) Patent Application Publication
(10) Pub. No.: US 2024/0219488 A1
(43) Pub. Date: Jul. 4, 2024

(54) MAGNETIC DETECTION DEVICE

(71) Applicant: ROHM CO., LTD., Kyoto (JP)

(72) Inventors: Eiji KUWAHARA, Kyoto (JP); Toru HIGUCHI, Kyoto (JP)

(73) Assignee: ROHM CO., LTD., Kyoto (JP)

(21) Appl. No.: 18/396,476

(22) Filed: Dec. 26, 2023

(30) Foreign Application Priority Data
Dec. 28, 2022 (JP) 2022-211465

(51) Int. Cl. G01R 33/07; G01R 33/00

(52) U.S. Cl. CPC G01R 33/072; G01R 33/0005; G01R 33/0011

(57) ABSTRACT

The present disclosure provides a magnetic detection device. The magnetic detection device includes: a magnetic detection element; and a magnetic flux converging member, disposed opposite to the magnetic detection element and configured to guide magnetic flux to the magnetic detection element. The magnetic flux converging member includes: a first magnetic flux converging portion, extending in a direction and facing the magnetic flux converging member with respect to the magnetic detection element, and a second magnetic flux converging portion, in a plan view seen from an opposing direction, protruding more laterally than the first magnetic flux converging portion. The magnetic flux converging member guides magnetic flux passing through the second magnetic flux converging portion to the magnetic detection element via the first magnetic flux converging portion.

### TECHNICAL FIELD

The present disclosure relates to a magnetic detection device.

### BACKGROUND

Regarding a conventional magnetic detection device, for example, patent publication 1 discloses a configuration of a packaged magnetic detection device in which a Hall element is mounted on a lead frame and the Hall element is sealed by a sealing resin.

### PRIOR ART DOCUMENT

### Patent Publication

[Patent document 1] Japan Patent Publication No. 2014-077730

### BRIEF DESCRIPTION OF THE DRAWINGS

FIG. 1 is a schematic cross-sectional view of a magnetic detection device according to a first embodiment.

FIG. 2 is a perspective view of a magnetic flux converging member according to the first embodiment.

FIG. 3 is a plan view of a positional relation between a magnetic flux converging member and a sensing unit of a magnetic detection device.

FIG. 4 is a schematic cross-sectional view of simulation results of magnetic flux guided by a magnetic flux converging member.

FIG. 5 is a schematic cross-sectional view of a magnetic detection device according to a second embodiment.

FIG. 6 is a schematic cross-sectional view of a magnetic detection device according to a third embodiment.

### DETAILED DESCRIPTION OF THE EMBODIMENTS

Details of the embodiments of a magnetic detection device of the present disclosure are given with the accompanying drawings below.

To keep the description clear and simple, the constituting elements shown in the accompanying drawings are not necessarily drawn to fixed scales. Moreover, for better understanding, shading lines may be omitted from the cross-sectional views. It should be noted that the accompanying drawings are for illustrating the embodiments of the present disclosure, and are not to be construed as limitations to the present disclosure.

The description below includes details for implementing a device a system and a method of the exemplary embodiments of the present disclosure. The detailed description is intended for illustration purposes and is not to be construed as limitations to the embodiments of the present disclosure or applications or uses of these embodiments.

### First Embodiment

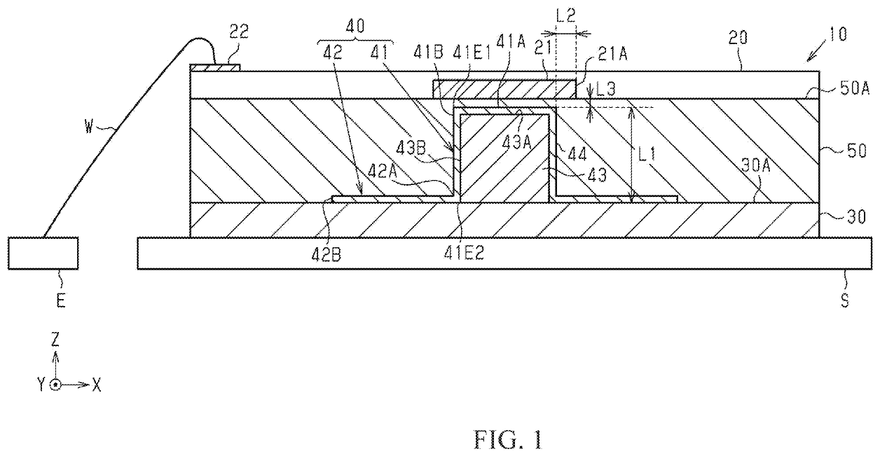

Referring to FIG. 1 to FIG. 3, a magnetic detection device 10 according to the first embodiment is described below.

FIG. 1 shows a schematic cross-sectional view of the magnetic detection device 10. Moreover, “X direction” used in the present disclosure refers to the X direction of X, Y and Z axes perpendicular to one another shown in FIG. 1, “Y direction” refers to a direction along the Y direction of the X, Y and Z axes, and “Z direction” refers to a direction along the Z direction of the X, Y and Z axes. A term such as “in a plan view” used in the present disclosure means observing the magnetic detection device 10 from top of the Z axis of the X, Y and Z axes.

The magnetic detection device 10 is formed as a magnetic detection device that is surface-mounted on a circuit substrate S of an electronic device. FIG. 1 shows the magnetic detection device 10 in a state of being surface-mounted on the circuit substrate S. The magnetic detection device 10 includes a magnetic detection element 20, a substrate 30 having an opposing surface 30A facing the magnetic detection element 20, and a magnetic flux converging member 40 disposed between the magnetic detection element 20 and the substrate 30 and configured to guide magnetic flux to the magnetic detection element 20. Moreover, the magnetic detection device 10 has an insulating layer 50 provided between the magnetic detection element 20 and the substrate 30. The magnetic flux converging member 40 is disposed in the insulating layer 50.

### (Magnetic Detection Element)

The magnetic detection element 20 detects magnetic flux passing through the magnetic detection element 20. The magnetic detection device 10 is configured to detect magnetism (a magnetic field) by detecting magnetic flux by the magnetic detection element 20.

The magnetic detection element 20 is not specifically defined, and can be implemented by a generally known sensor for detecting magnetic flux. The magnetic detection element 20 is, for example, a Hall element, which includes a semiconductor layer including P-type silicon, and an N-type semiconductor region serving as a diffusion layer formed by introducing an N-type impurity to a surface of the semiconductor layer. Moreover, the magnetic detection element 20 can also be an element other than a Hall element.

The magnetic detection element 20 is disposed on an upper surface 50A of the insulating layer 50, that is, a surface of the insulating layer 50 on an opposite side of the substrate 30. The magnetic detection element 20 includes a sensing unit 21 for detecting magnetic flux, and an electrode pad 22 which is an external connection terminal. The sensing unit 21 and the electrode pad 22 are electrically connected by a wiring (not shown). The electrode pad 22 is electrically connected to an external electrode E by a conductive wire W. The conductive wire W is a bonding wire formed by a wire bonding device. Each of the electrode pad 22 and the conductive wire W is made of, for example, a conductor such as Au, Al and Cu.

### (Substrate)

The substrate 30 is a component that becomes the basis of the magnetic detection device 10. The substrate 30 includes a semiconductor material which is a monocrystalline material. In one example, the substrate 30 is a Si-containing monocrystalline material. The substrate 30 has an opposing surface 30A facing the magnetic detection element 20, and has a tablet shape with the Z direction as a thickness direction. The opposing surface 30A is a surface in parallel to the X direction and the Y direction.

In a plan view, the substrate 30 has a rectangular shape having sides extending in the X direction and sides extending in the Y direction, wherein a size in the X direction is greater than a size in the Y direction. Moreover, the shape of the substrate 30 in the plan view is not limited to the rectangular shape above, but can be other shapes such as a square, a polygon or a circle.

### (Magnetic Flux Converging Member).

As shown in FIG. 1, the magnetic flux converging member 40 is disposed on the opposing surface 30A of the substrate 30, and is configured to face the magnetic detection element 20. In the description below, sometimes a direction (the Z direction) in which the magnetic flux converging member 40 faces the magnetic detection element 20 is described as an opposing direction of the magnetic flux converging member 40.

The magnetic flux converging member 40 includes a first magnetic flux converging portion 41 and a second magnetic flux converging portion 42. The first magnetic flux converging portion 41 is a part that faces the magnetic detection element 20 and extends along the opposing direction of the magnetic flux converging member 40. The second magnetic flux converging portion 42 is a part protruding more laterally than the first magnetic flux converging portion 41 in the plan view. The magnetic flux converging member 40 guides magnetic flux passing through the second magnetic flux converging portion 42 to the magnetic detection element 20 through the first magnetic flux converging portion 41.

Moreover, the magnetic flux converging member 40 can be disposed on the opposing surface 40A to be in contact with the opposing surface 30A of the substrate 30, or can be disposed on the opposing surface 30A with another component interposing in between. As an example in FIG. 1, a case where the magnetic flux converging member 40 is disposed on the opposing surface 30A to be in contact with the opposing surface 30A of the substrate 30 is shown.

### [First Magnetic Flux Converging Portion]

The first magnetic flux converging portion 41 includes a support portion 43 having a cylindrical shape and erecting from the substrate 30 toward the magnetic detection element 20, and a magnetic film 44 coated on a surface of the support portion 43.

The support portion 43 is disposed on the opposing surface 30A of the substrate 30. The support portion 43 is formed of, for example, a non-magnetic material such as Cu. Moreover, the support portion 43 can be formed of a magnetic material.

The support portion 43 has an upper surface 43A on an end of the support portion 43 located on a side of the magnetic detection element 20, and a side surface 43B extending from an end of the support portion 43 on a side of the substrate 30 toward the upper surface 43A. The upper surface 43A of the support portion 43 is a plane perpendicular to the opposing direction of the magnetic flux converging member 40. The side surface 43B of the support portion 43 is an upright surface in parallel to the opposing direction of the magnetic flux converging member 40. In other words, the upright surface is a surface perpendicular to the opposing surface 30A of the substrate 30. Moreover, the side surface 43B of the support portion 43 can also be an inclined surface inclined relative to the opposing direction of the magnetic flux converting member 40. Moreover, in a case where the support portion 43 has a shape with multiple side surfaces 43B, the support portion 43 can also include one or more of the upright surfaces as the side surface 43B and one or more inclined surfaces as the side surface 43B.

The support portion 43 has a profile of, for example, a polygonal prism shape such as a quadrilateral prism shape having a constant cross-sectional area from the opposing surface 30A of the substrate 30 toward the magnetic detection element 20. Moreover, the support portion 43 also have a profile of, for example, a polygonal pyramid shape such as a quadrilateral pyramid shape having a cross-sectional area gradually decreasing from the opposing surface 30A of the substrate 30 toward the magnetic detection element 20. An example where the support portion 43 is formed to have a rectangular prism shape is described below. In a case where the support portion 43 has a rectangular prism shape, all of the four side surfaces 43B of the support portion 43 are the upright surfaces.

The magnetic film 44 is provided on a surface of the support portion 43, that is, on the upper surface 43A and each side surface 43B of the support portion 43. The magnetic film 44 is formed of a magnetic material. The magnetic material forming the magnetic film 44 is, for example, ferrite, Fe and Ni. A film thickness of the magnetic film 44 is, for example, between about 0.1 micrometer (μm) and about 50 μm. The film thickness of the magnetic film 44 can be globally constant or be partially different.

The first magnetic flux converging portion 41 includes a magnetic flux converging opposing surface 41A located on an end 41E1 of the first magnetic flux converging portion 41 on a side of the magnetic detection element 20 and facing the magnetic detection element 20, and a magnetic flux converging side surface 41B extending from an end 41E2 of the first magnetic flux converging portion 41 on an opposite side of the end 41E1 toward the magnetic flux converging opposing surface 41A. The magnetic flux converging opposing surface 41A and the magnetic flux converging side surface 41B are surfaces formed by the magnetic film 44.

Preferably, a length L1 of the magnetic flux converging member 40 in the opposing direction, which is a height size of the first magnetic flux converging portion 41, is longer. The length L1 of the first magnetic flux converging portion 41 is a length from the end 41E2 of the first magnetic flux converging portion 41 on the side of the substrate 30 to the end 41E1 on the side of the magnetic detection element 20. The length L1 of the first magnetic flux converging portion 41 can be adjusted by means of modifying one or both of a protruding height (the length in the Z direction) of the support portion 43 and the film thickness of the magnetic film 44. The length L1 of the first magnetic flux converging portion 41 is, for example, between about 0.2 μm and about 200 μm, preferably between about 10 μm and about 150 μm, and more preferably between about 50 μm and about 150 μm.

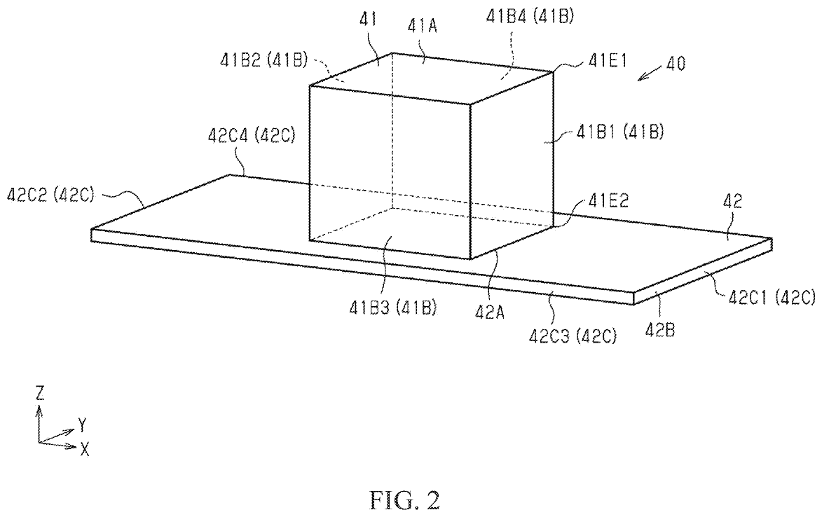

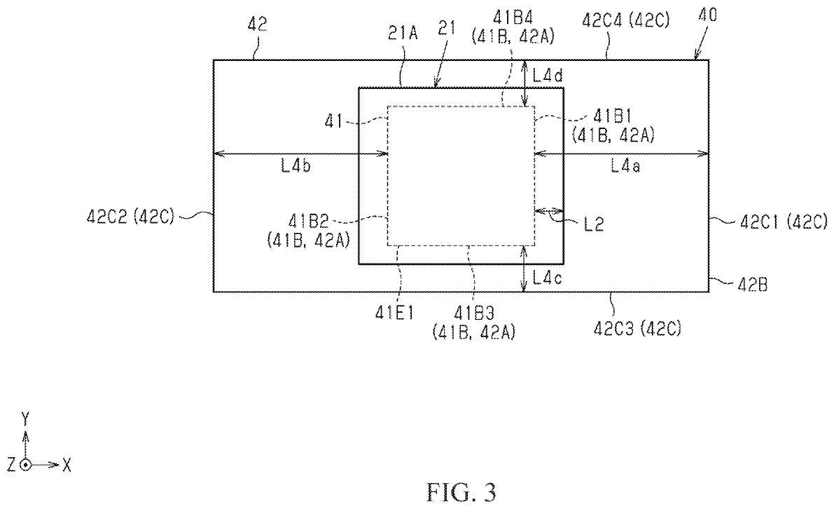

FIG. 2 shows a perspective view of the magnetic flex converting member 40, and FIG. 3 shows a plan view of a position relation between the magnetic flux converging member 40 and the sensing unit 21 of a magnetic detection element 20. FIG. 2 and FIG. 3 show an example of the shape of the magnetic flux converging member 40. An overall shape of the first magnetic flux converging portion 41 shown in FIG. 2 and FIG. 3 is specifically described below.

The first magnetic flux converging portion 41 has a rectangular shape with the opposing direction of the magnetic converging member 40 as a height direction. Thus, the first magnetic flux converging portion 41 has a rectangular shape in the plan view. The shape of the first magnetic flux converging portion 41 is a shape formed by enlarging the profile of the support portion 43 by the part of the magnetic film 44, and is similar to the profile of the support portion 43. The first magnetic flux converging portion 41 has the magnetic flux converging opposing surface 41A facing one side (the side of the magnetic detection element 20) in the Z direction, and four magnetic flux converging side surfaces 41B facing the X direction or the Y direction in the plan view. The magnetic flux converging side surfaces 41B include magnetic flux converging side surfaces 41B1 and 41B2 facing the X direction and in parallel to the Y direction, and magnetic flux converging side surfaces 41B3 and 41B4 facing the Y direction and in parallel to the X direction. The four magnetic flux converging side surfaces 41B are upright surfaces in parallel to the opposing direction (the Z direction) of the magnetic flux converging member 40. In the plan view, the first magnetic flux converging portion 41 has a rectangular shape having a greater size in the X direction than in the Y direction. Moreover, the overall shape of the first magnetic flux converging portion 41 is not limited to the shape shown in FIG. 2 and FIG. 3. For example, the overall shape of the first magnetic flux converging portion 41 can also be a polygonal pyramid shape such as a quadrilateral pyramid shape.

Next, the configuration of the first magnetic flux converging portion 41 is described below.

As shown in FIG. 1 and FIG. 3, in the opposing direction (the Z direction) of the magnetic flux converging member 40, the first magnetic flux converging portion 41 is disposed on a position overlapping the sensing unit 21 of the magnetic detection element 20. More particularly, preferably, at least portion of an end 41E1 of the magnetic flux converging side surface 41B of the first magnetic flux converging portion 41 on the side of the magnetic detection element 20 overlaps the sensing unit 21 of the magnetic detection element 20. In this case, the effect of guiding magnetic flux converged at the magnetic flux converging side surface 41B of the first magnetic flux converging portion 41 to the sensing unit 21 of the magnetic detection element 20 can be enhanced.

Thus, preferably, all ends of the magnetic side surface 41B of the first magnetic collecting unit 41 on a side of the magnetic detection element 20, that is, all of the ends 41E1 of the magnetic side surfaces 41B of the first magnetic collecting unit 41 on a side of the magnetic detection element 20, are configured to overlap the sensing unit 21 of the magnetic detection element 20. As an example in FIG. 2 and FIG. 3, it is shown that all of the ends 41E1 of the magnetic flux converging side surface 41B of the first magnetic flux converging portion 41 on the side of the magnetic detection element 20 are a state of overlapping the sensing unit 21 of the magnetic detection element 20.

Moreover, as shown in FIG. 1 and FIG. 3, in the opposing direction of the magnetic flux converging member 40, the position of the end 41E1 of the magnetic flux converging side surface 41B overlapping the sensing unit 21 is preferably close to a central side of the sensing unit 21 than an outer periphery 21A of the sensing unit 21. In other words, in the plan view, at least a portion of the outer periphery 21A of the sensing unit 21 preferably protrudes from the end 41E1 of the magnetic flux converging side surface 41B on the side of the magnetic detection element 20, and preferably, the outer periphery 21A of the sensing unit 20 entirely protrudes from the end 41E1 of the magnetic flux converging side surface 41B on the side of the magnetic detection element 20. In this case, a distance L2 from the outer periphery 21A of the sensing unit 21 to the end 41E1 of the magnetic flux converging side surface 41B on the side of the magnetic detection element 20 is, for example, between about 0.1 μm and about 50 μm. Moreover, when the distance L2 is, for example, in a case of the magnetic flux converging member 40 shown in FIG. 2, at least one of a distance from the magnetic flux converging side surface 41B1 to the outer periphery 21A of the sensing unit 21, a distance from the magnetic flux converging side surface 41B2 to the outer periphery 21A of the sensing unit 21, a distance from the magnetic flux converging side surface 41B3 to the outer periphery 21A of the sensing unit 21, and a distance from the magnetic flux converging side surface 41B4 to the outer periphery 21A of the sensing unit 21.

As shown in FIG. 1, in the opposing direction of the magnetic flux converging member 40, the first magnetic flux converging portion 41 can be separated from the sensing unit 21 of the magnetic detection element 20 or be in contact with the sensing unit 21. When the first magnetic flux converging portion 41 is separated from the sensing unit 21, short-circuitry between the first magnetic flux converging portion 41 and the sensing unit 21 can be inhibited. A separation distance L3 between the first magnetic flux converging portion 41 and the sensing unit 21 is, for example, between about 0.1 μm and about 100 μm. When the first magnetic flux converging portion 41 is separated from the sensing unit 21, preferably, the insulating layer 50 is interposed between the first magnetic flux converging portion 41 and the sensing unit 21.

### [Second Magnetic Flux Converging Portion]

As shown in FIG. 1, the second magnetic flux converging portion 42 is a part extending as a tablet on the opposing surface 30A of the substrate 30. The second magnetic flux converging portion 42 is formed of a magnetic material. The magnetic material forming the second magnetic flux converging portion 42 is, for example, ferrite, Fe and Ni. In one example, the second magnetic flux converging portion 42 is made of a same material as the magnetic film 44, and is formed to be continuous with the magnetic film 44. A thickness of the second magnetic flux converging portion 42 is, for example, between about 0.1 μm and about 50 μm.

The second magnetic flux converging portion 42 protrudes laterally from the end 41E2 of the first magnetic flux converging portion 41 on the side of the substrate 30. The so-called “protruding laterally” means protruding in a direction (along a direction of the X-Y plane) perpendicular to the opposing direction (the Z direction) of the magnetic flux converging member 40. The second magnetic flux converging portion 42 can protrude in a specific direction or multiple specific directions perpendicular to the opposing direction of the magnetic flux converging member 40, or can protrude in all of the directions perpendicular to the opposing direction.

The second magnetic flux converging portion 42 has a base portion 42A continuous with the first magnetic flux converging portion 41, and a tip portion 42B located at an outer periphery of the second magnetic flux converging portion 42 in the plan view. Preferably, in the plan view, at least a portion of the tip portion 42B of the second magnetic flux converging portion 42 protrudes from the sensing unit 21 of the magnetic detection element 20, and more preferably, the tip portion 42B entirely protrudes from the sensing unit 21 of the magnetic detection element 20. Moreover, the second magnetic flux converging portion 42 can also have a shape in which the tip portion 42B does not protrude from the sensing unit 21 of the magnetic detection element 20 in the plan view.

FIG. 2 and FIG. 3 show an example of the shape of the magnetic flux converging member 40. A shape of the second magnetic flux converging portion 42 shown in FIG. 2 and FIG. 3 is specifically described below. The second magnetic flux converging portion 42 has a rectangular profile in the plan view. The second magnetic flux converging portion 42 has four sides 42C each located on four sides of a rectangle and in parallel to the X direction or the Y direction. Each of the four sides 42C is the tip portion 42B of the second magnetic flux converging portion 42. Moreover, the four sides 42C include a first side 42C1 and a second side 42C2 in parallel to the Y direction, and a third side 42C3 and a fourth side 42C4 in parallel to the X direction.

Herein, the second magnetic flux converging portion 42 is preferably formed to be wider in the plan view. By forming the second magnetic flux converging portion 42 to be wider, magnetic flux can be converged within a broader range. For example, as shown in FIG. 3, when the shape of the second magnetic flux converging portion 42 in the plan view is a rectangle shape in parallel to the X direction and the Y direction, at least one of distances LAa to L4d from the based portion 42A of the second magnetic flux converging portion 42 to the first side 42C1 to the fourth side 42C4 is more than 0.1 μm. The distance LAa is a distance from the base portion 42A (the magnetic flux converging side surface 41B1) of the second magnetic flux converging portion 42 to the first side 42C1. The distance LAb is a distance from the base portion 42A (the magnetic flux converging side surface 41B2) of the second magnetic flux converging portion 42 to the second side 42C2. The distance LAc is a distance from the base portion 42A (the magnetic flux converging side surface 41B3) of the second magnetic flux converging portion 42 to the third side 42C3. The distance L4d is a distance from the base portion 42A (the magnetic flux converging side surface 41B4) of the second magnetic flux converging portion 42 to the fourth side 42C4. Moreover, the magnetic flux converging effect of the second magnetic flux converging portion 42 formed to be wider has its upper limit. Thus, from the perspective of inhibiting overly enlarging the magnetic flux converging member 40, the lengths L4a to L4d are limited to be less than 250 μm, for example.

Moreover, the shape of the second magnetic flux converging portion 42 is not limited to the shape shown in FIG. 2 and FIG. 3. For example, the shape of the second magnetic flux converging portion 42 in the plan view can also have other shapes such as a square, a polygon or a circle. Moreover, in the plan view, the second magnetic flux converging portion 42 can also be only partially provided on a portion of an outer peripheral region of the first magnetic flux converging portion 41. For example, in a case where the first magnetic flux converging portion 41 has a rectangular shape in the plan view with the magnetic flux converging side surfaces 41B1 to 41B4, in one example, the shape of the second magnetic flux converging portion 42 in the plan view is a shape having a part protruding from two of the magnetic flux converging side surfaces 41B facing opposite directions from each other (for example, the magnetic flux converging side surfaces 41B1 and 41B2), but does not have a part protruding from the remaining two magnetic flux converging side surfaces (for example, the magnetic flux converging side surfaces 41B3 and 41B4). In another example, the shape of the second magnetic flux converging portion 42 in the plan view is a shape having a part protruding from two of the magnetic flux converging side surfaces 41B adjacent to each other (for example, the magnetic flux converging side surfaces 41B1 and 41B3), but does not have a part protruding from the remaining two magnetic flux converging side surfaces (for example, the magnetic flux converging side surfaces 41B2 and 41B4).

### (Insulating Layer)

The insulating layer 50 can be made of at least one of an insulative resin material containing epoxy, silicon dioxide (SiO₂), silicon nitride (SiN), silicon oxynitride (SiON), aluminum oxide (Al₂O₃), aluminum nitride (AlN) and aluminum oxynitride (AlON).

As shown in FIG. 1, the insulating layer 50 is formed on the substrate 30 to cover the opposing surface 30A of the substrate 30 and the magnetic flux converging member 40. An entire surface of the magnetic flux converging member 40, that is, entire surfaces of the magnetic flux converging opposing surface 41A and the magnetic flux converging side surfaces 41B of the first magnetic flux converging portion 41 as well as the second magnetic flux converging portion 42, is covered by the insulating layer 50. The insulating layer 50 has an upper surface 50A located on an opposite side to the substrate 30. The upper surface 50A is a plane perpendicular to the opposing direction of the magnetic flux converging member 40. The magnetic detection element 20 is disposed on the upper surface 50A of the insulating layer 50.

### (Effects)

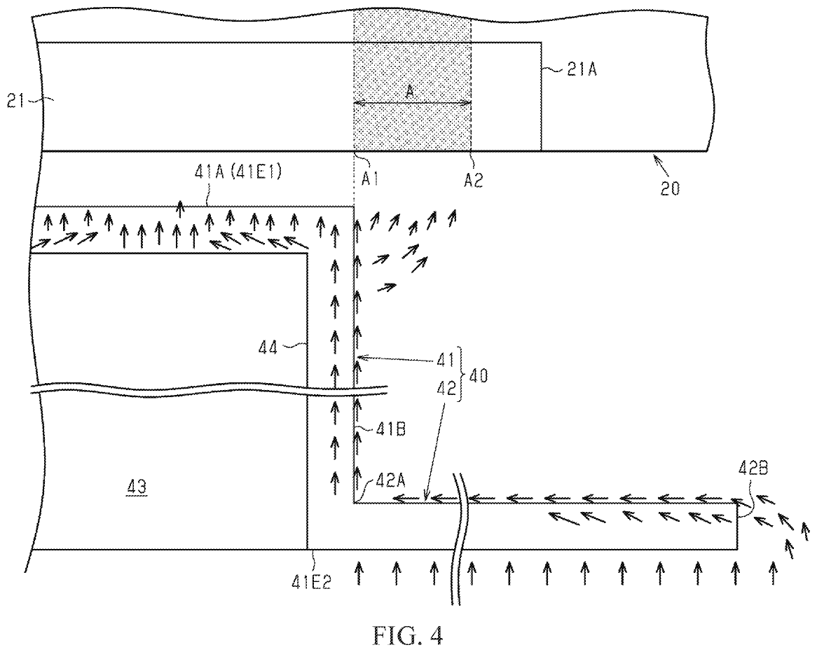

Next, referring to FIG. 4, effects of the magnetic detection device 10 of the first embodiment are described below.

FIG. 4 shows an enlarged partial view of the magnetic detection device 10 in FIG. 1, and depicts only the magnetic flux converging member 40 and the magnetic detection element 20. The small arrows in FIG. 4 indicate simulation results of applying, to the magnetic detection device 10, a magnetic field that generates magnetic flux in a direction from the side of a circuit substrate S toward the magnetic detection device 10 (the opposing direction of the magnetic flux converging member 40), and directions of magnetic flux around the magnetic flux converging member 40.

As shown in FIG. 4, magnetic flux passing through the second magnetic flux converging portion 42 of the magnetic flux converging member 40 is guided from the side of the tip portion 42B of the second magnetic flux converging portion 42 to the base portion 42A via a surface and an interior of the second magnetic flux converging portion 42. The magnetic flux having arrived at the base portion 42A of the second magnetic flux converging portion 42 is guided from the side of the end 41E2 of the first magnetic flux converging portion 41 to the side of the end 41E1 via the magnetic flux converging side surface 41B of the first magnetic flux converging portion 41 and an interior of the first magnetic flux converging portion 41.

The magnetic flux having reached the end 41E1 of the first magnetic flux converging portion 41 via the magnetic flux converging side surface 41B of the first magnetic flux converging portion 41 expands toward one side facing the magnetic flux converging side surface 41B, and is at the same time guided to the sensing unit 21 of the magnetic detection element 20. Moreover, the magnetic flux having reached the end 41E1 of the first magnetic flux converging portion 41 via the interior of the first magnetic flux converging portion 41 expands to the magnetic flux converging opposing surface 41A of the first magnetic flux converging portion 41, and is at the same time guided to the sensing unit 21 of the magnetic detection element 20.

As such, the magnetic flux converging member 40 converges the magnetic flux passing through the second magnetic flux converging portion 42 to the first magnetic flux converging portion 41, and guides the magnetic flux to the sensing unit 21 of the magnetic detection element 20 disposed opposite to the first magnetic flux converging portion 41 through the first magnetic flux converging portion 41. Accordingly, a density of magnetic flux passing through the sensing unit 21 of magnetic detection element 20 is increased. As a result, the detection accuracy of the magnetic detection element 20 is improved.

Moreover, in the simulation results, when the magnetic flux converging member 40 is provided, the density of magnetic flux passing through the magnetic detection element 20 is the highest in a predetermined range A, and gradually decreases as getting away from the predetermined range A. The predetermined range A in the magnetic detection element 20 is a range from a position A1 overlapping the magnetic flux converging side surface 41B in the opposing direction to a position A2 located at a predetermined distance on the side (an opposing direction of the magnetic flux converging side surface 41B) of the magnetic flux converging side surface 41B. It is known from the simulation results that, by configuring the sensing unit 21 of the magnetic detection element 20 to be at least partially located within the predetermined range A, the density of magnetic flux passing through the sensing unit 21 can be further increased.

### (Effects)

The magnetic detection device 10 according to the first embodiment achieves the following effects.

(1-1)

The magnetic detection device 10 includes the magnetic flux converging element 20, and the magnetic flux converging member 40 disposed opposite to the magnetic detection element 20 and configured to guide magnetic flux to the magnetic detection element 20. The magnetic flux converging member 40 includes the first magnetic flux converging portion 41 extending in a direction and facing the magnetic flux converging member 40 with respect to the magnetic detection element 20, and the second magnetic flux converging portion 42 protruding more laterally than the first magnetic flux converging portion 41 when viewed in a plan view from an opposing direction.

The magnetic flux converging member 40 guides magnetic flux passing through the second magnetic flux converging portion 42 to the magnetic detection element 20 through the first magnetic flux converging portion 41. According to the configuration above, magnetic flux passing through the second magnetic flux converging portion 42 of the magnetic flux converging member 40 is guided to the magnetic detection element 20 via the second magnetic flux converging portion 42 and the first magnetic flux converging portion 41. Accordingly, a density of magnetic flux passing through the magnetic detection element 20 can be increased. As a result, the detection accuracy of the magnetic detection device 10 is improved.

(1-2)

The base portion 42A of the second magnetic flux converging portion 42 is continuous with the end 41E2 of the first magnetic flux converging portion 41. According to the configuration above, magnetic flux can be effectively guided from the second magnetic flux converging portion 42 to the first magnetic flux converging portion 41. Thus, the effect of (1-1) is made even greater.

(1-3)

At least a portion of the tip portion 42B of the second magnetic flux converging portion 42 protrudes from the sensing unit 21 of the magnetic detection element 20 in the plan view. According to the configuration above, in the plan view, magnetic flux passing around the sensing unit 21 of the magnetic detection element 20 can be guided to the sensing unit 21 via the second magnetic flux converging portion 42. Thus, the effect of (1-1) is made even greater.

(1-4)

The tip portion 42B of the second magnetic flux converging portion 42 has the first side 42C1, the second side 42C2, the third side 42C3 and the fourth side 42C4 each located at four sides of a rectangular shape. In the second magnetic flux converging portion 42, at least one of the distance L4a from the base portion 42A to the first side 42C1, the distance LAb from the base portion 42A to the second side 42C2, the distance LAc from the base portion 42A to the third side 42C3, and the distance L4d from the base portion 42A to the fourth side 42C4 is between about 0.1 μm and about 250 μm.

According to the configuration above, magnetic flux can be converged within a broader range via the second magnetic flux converging portion 42. Thus, the effect of (1-1) is made even greater. Moreover, the magnetic flux converging effect of the second magnetic flux converging portion 42 formed to be wider has its upper limit. Thus, by setting the distance to be less than about 250 μm, magnetic flux converging efficiency per unit area of the second magnetic flux converging portion 42 can be further improved. Thus, with the magnetic flux converging member 40 provided, the magnetic detection accuracy of the magnetic detection device 10 can be improved and an overly large size increase in the magnetic detection device 10 can be inhibited.

(1-5)

The first magnetic flux converging portion 41 includes the support portion 43 having a cylindrical shape extending toward the magnetic detection element 20, and the magnetic film 44 coated on the surface of the support portion 43. According to the configuration above, only the surface of the first magnetic flux converging portion 41 is formed of a magnetic material. Thus, magnetic flux passing through the first magnetic flux converging portion 41 is converged on the surface of the first magnetic flux converging portion 41. Accordingly, the effect of guiding the magnetic flux in the first magnetic flux converging portion 41 to the magnetic detection element 20 is further enhanced. As a result, the detection accuracy of the magnetic detection device 10 is further improved.

(1-6)

The first magnetic flux converging portion 41 has the magnetic flux converging side surfaces 41B which are continuous side surfaces with the second magnetic flux converging portion 42. The magnetic flux converging side surfaces 41B include upright surfaces in parallel to the opposing direction. The effect of guiding magnetic flux to the magnetic detection element 20 by the first magnetic flux converging portion 41 increases as the magnetic flux converging side surfaces 41B of the first magnetic flux converging portion 41 get more parallel with respect to the opposing direction of the magnetic flux converging member 40. Thus, according to the configuration above, the effect of guiding the magnetic flux in the first magnetic flux converging portion 41 to the magnetic detection element 20 is enhanced. As a result, the detection accuracy of the magnetic detection device 10 is further improved.

(1-7)

The first magnetic flux converging portion 41 has a rectangular shape with the opposing direction as a height direction. According to the configuration above, all of the magnetic flux converging side surfaces 41B of the first magnetic flux converging portion 41 are upright surfaces, and so the effect of (1-6) is made even greater.

(1-8)

In the opposing direction, the length L1 of the first magnetic flux converging portion 41 is, for example, between about 0.1 μm and about 200 μm. The effect of guiding magnetic flux to the sensing unit 21 through the first magnetic flux converging portion 41 increases as the length L1 increases, and reaches an upper limit when the length L1 becomes a length greater than a certain length. Thus, according to the configuration above, magnetic flux converging efficiency per unit length is further improved. Thus, with the magnetic flux converging member 40 provided, the magnetic detection accuracy of the magnetic detection device 10 can be improved and an overly large size increase in the magnetic detection device 10 can be inhibited.

(1-9)

The magnetic detection element 20 includes the sensing unit 21 for detecting magnetic flux. The sensing unit 21 is separated from the first magnetic flux converging portion 41 of the magnetic flux converging member 40 in the opposing direction. The separation distance L3 between the sensing unit 21 and the first magnetic flux converging portion 41 is between about 0.1 μm and about 100 μm. According to the configuration above, since the first magnetic flux converging portion 41 is disposed at a position near the sensing unit 21, magnetic flux can be effectively guided from the end 41E1 of the first magnetic flux converging portion 41 to the magnetic detection element 20. As a result, the detection accuracy of the magnetic detection device 10 is further improved.

(1-10)

At least a portion of the sensing unit 21 of the magnetic detection element 20 protrudes from the first magnetic flux converging portion 41 of the magnetic flux converging member 40 in the plan view. According to the configuration above, the sensing unit 21 can be disposed within the predetermined range A, which is a part with a higher density of magnetic flux. Accordingly, a density of magnetic flux passing through the sensing unit 21 can be increased. As a result, the detection accuracy of the magnetic detection device 10 is further improved.

### Second Embodiment

A magnetic detection device 110 of the second embodiment primarily differs from the first embodiment in terms of the configuration of the magnetic flux converging member 40. In the description below, associated details of the constituting elements common with those of the first embodiment are omitted for brevity, and only details of constituting elements different from those of the first embodiment are described.

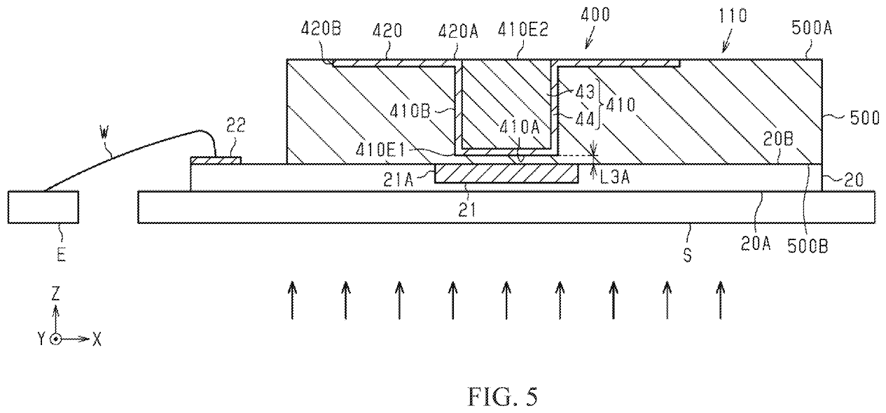

FIG. 5 shows a schematic cross-sectional view of the magnetic detection device 110 in a state of being surface-mounted on the circuit substrate S. The magnetic detection device 110 includes a magnetic detection element 20, and a second magnetic flux converging member 400 configured to guide magnetic flux to the magnetic detection element 20.

The magnetic detection element 20 is disposed on a circuit substrate S. The magnetic detection element 20 is, for example, a Hall element, which includes a semiconductor layer including P-type silicon, and an N-type semiconductor region serving as a diffusion layer formed by introducing an N-type impurity to a surface of the semiconductor layer. The magnetic detection element 20 includes a sensing unit 21 for detecting magnetic flux, and an electrode pad 22 which is an external connection terminal.

The magnetic detection element 20 has a first surface 20A, and a second surface 20B located on an opposite side of the first surface 20A. The first surface 20A of the magnetic detection element 20 is a surface for mounting to the circuit substrate S. The second magnetic flux converging member 400 is disposed on the second surface 20B of the magnetic detection element 20. Moreover, the magnetic detection device 110 has an insulating layer 500 provided on the second surface 20B of the magnetic detection element 20. The second magnetic flux converging member 400 is disposed in the insulating layer 500. The insulating layer 500 has an upper surface 500A, and a lower surface 500B located on an opposite side of the upper surface 500A. The lower surface 500B of the insulating layer 500 is in contact with the second surface 20B of the magnetic detection element 20. Moreover, the electrode pad 22 of the magnetic detection element 20 is exposed from the insulating layer 500.

The second magnetic flux converging member 400 includes a first magnetic flux converging portion 410 and a second magnetic flux converging portion 420. The first magnetic flux converging portion 410 is a part that faces the magnetic detection element 20 and extends along an opposing direction of the second magnetic flux converging member 400. The second magnetic flux converging portion 420 is a part protruding more laterally than the first magnetic flux converging portion 410 in the plan view. The second magnetic flux converging member 400 guides magnetic flux passing through the second magnetic flux converging portion 420 to the magnetic detection element 20 through the first magnetic flux converging portion 410. Moreover, the opposing direction of the second magnetic flux converging member 400 refers to a direction (the Z direction) in which the magnetic detection element 20 is opposite to the second magnetic flux converging member 400.

The first magnetic flux converging portion 410 includes a magnetic flux converging opposing surface 410A located on an end 410E1 of the first magnetic flux converging portion 410 on a side of the magnetic detection element 20 and facing the magnetic detection element 20, and a magnetic flux converging side surface 410B extending from the magnetic flux converging opposing surface 410A toward an end 410E2 of the first magnetic flux converging portion 410 on an opposite side of the magnetic detection element 20. Apart from a direction in which the opposing direction (the Z direction) of the second magnetic flux converging member 400 is formed to be opposite, the configuration of the first magnetic flux converging portion 410 is the same as the first magnetic flux converging portion 41 of the first embodiment. Thus, the shape and size as well as the arrangement in the plan view of the first magnetic flux converging portion 410 can be implemented by the same configuration as the first magnetic flux converging portion 41 of the first embodiment.

In the opposing direction of the second magnetic flux converging member 400, the first magnetic flux converging portion 410 can be separated from the sensing unit 21 of the magnetic detection element 20 or be in contact with the sensing unit 21. A separation distance L3A between the first magnetic flux converging portion 410 and the sensing unit 21 is, for example, between about 0.1 μm and about 100 μm. When the first magnetic flux converging portion 410 is separated from the sensing unit 21, preferably, the insulating layer 500 is interposed between the first magnetic flux converging portion 410 and the sensing unit 21.

The second magnetic flux converging portion 420 is a part extending as a tablet on the upper surface 500A of the insulating layer 500. The second magnetic flux converging portion 420 protrudes laterally from the end 410E1 of the first magnetic flux converging portion 410. The second magnetic flux converging portion 420 has a base portion 420A continuous with the first magnetic flux converging portion 410, and a tip portion 420B located at an outer periphery of the second magnetic flux converging portion 420 in the plan view. Preferably, in the plan view, at least a portion of the tip portion 420B of the second magnetic flux converging portion 420 protrudes from the sensing unit 21 of the magnetic detection element 20, and more preferably, the tip portion 420B entirely protrudes from the sensing unit 21 of the magnetic detection element 20. Moreover, the second magnetic flux converging portion 420 can also have a shape in which the tip portion 420B does not protrude from the sensing unit 21 of the magnetic detection element 20 in the plan view.

Apart from being formed on the upper surface 500A of the insulating layer 500, the configuration of the second magnetic flux converging portion 420 is the same as the second magnetic flux converging portion 42 of the first embodiment. Thus, the shape and size as well as the arrangement in the plan view of the second magnetic flux converging portion 420 can be implemented by the same configuration as the second magnetic flux converging portion 42 of the first embodiment.

### (Effects)

The magnetic detection device 110 according to the second embodiment achieves the same effects as the magnetic detection device 10 of the first embodiment. Moreover, the magnetic detection device 110 according to the second embodiment further achieves the following effects.

(2-1)

The magnetic detection element 20 has the first surface 20A as a mounting surface upon mounting of the magnetic detection device 110, and the second surface 20B located on an opposite side of the first surface 20A. The second magnetic flux converging member 400 is disposed on the second surface 20B of the magnetic detection element 20. The second magnetic flux converging member 400 includes the first magnetic flux converging portion 410 facing the magnetic detection element 20 and extending in the opposing direction of the second magnetic flux converging member 400, and the second magnetic flux converging portion 420 protruding more laterally than the first magnetic flux converging portion 410 in the plan view.

According to the configuration above, magnetic flux from the circuit substrate S mounted with the magnetic detection element 20 toward a direction of the magnetic detection element 20 (magnetic flux indicated by the small arrows in FIG. 5), and magnetic flux passing around the sensing unit 21 of the magnetic detection element 20, are guided to the sensing unit 21 of the magnetic detection element 20 via the second magnetic flux converging portion 420 and the first magnetic flux converging portion 410. As a result, similar to the first embodiment, the detection accuracy of the magnetic detection device 110 is improved.

### Third Embodiment

A magnetic detection device 120 of the third embodiment differs from the first embodiment in that, the second magnetic flux converging member 400 of the second embodiment is added. In the description below, associated details of the constituting elements common with those of the first embodiment and the second embodiment are omitted for brevity, and only details of constituting elements different from those of the first embodiment are described.

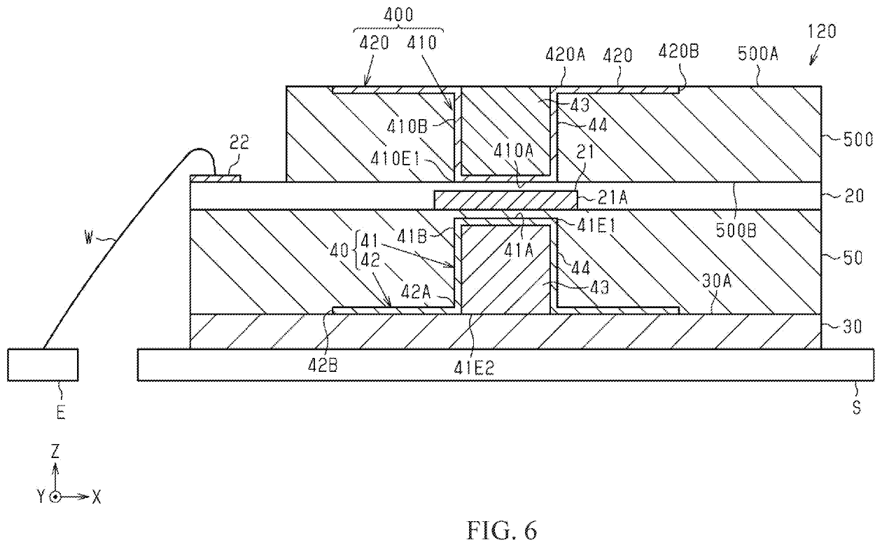

FIG. 6 shows a schematic cross-sectional view of the magnetic detection device 120 in a state of being surface-mounted on the circuit substrate S. The magnetic detection device 120 includes a magnetic detection element 20, a substrate 30 having an opposing surface 30A facing the magnetic detection element 20, and a magnetic flux converging member 40 (the first magnetic flux converging member 40) and a second magnetic flux converging member 400 guiding magnetic flux to the magnetic detection element 20. In the description associated with the third embodiment, the magnetic flux converging member 40 is described as the first magnetic flux converging member 40. Moreover, the magnetic detection device 120 has an insulating layer 50 provided between the magnetic detection element 20 and the substrate 30, and an insulating layer 500 provided on the magnetic detection element 20.

The respective arrangement and configuration details of the magnetic detection element 20, the substrate 30, the first magnetic flux converging member 40 and the insulating layer 50 are the same as the first embodiment. The respective arrangement and configuration details of the second magnetic flux converging member 400 and the insulating layer 500 are the same as the second embodiment.

The shapes and sizes of the first magnetic flux converging member 40 and the second magnetic flux converging member 400 can be the same, or can be partially or entirely different. For example, the profile of the first magnetic flux converging portion 41 of the first magnetic flux converging member 40 is set to be a rectangular prism shape, and the profile of the first magnetic flux converging portion 410 of the second magnetic flux converging member 400 can be set to be a quadrilateral pyramid shape.

The magnetic detection device 120 according to the third embodiment achieves the same effects as the magnetic detection device 10 of the first embodiment. Moreover, the magnetic detection device 120 according to the third embodiment further achieves the following effects.

(3-1)

The present disclosure includes the substrate 30 having the opposing surface 30A facing the magnetic detection element 20. The magnetic detection element 20 has the first surface 20A facing the substrate 30, and the second surface 20B located on an opposite side of the first surface 20A. The magnetic flux converging members include the first magnetic flux converging member 40 disposed between the first surface 20A of the magnetic detection element 20 and the opposing surface 30A of the substrate 30, and the second magnetic flux converging member 400 disposed on the second surface 20B of the magnetic detection element 20. According to the configuration above, compared to the configuration using only the first magnetic flux converging member 40 as a magnetic flux converging member, more magnetic flux can be guided to the magnetic detection element 20. As a result, compared to the magnetic detection device 10 of the first embodiment, the detection accuracy is improved.

### VARIATION EXAMPLES

The embodiments can be modified as follows and be accordingly implemented as below. Given that no technical contradiction is resulted, the embodiments and the following variation examples may be used in combination. Moreover, in the variation examples below, parts that are common with the embodiment describe above are denoted by the same numerals and symbols, and the related description is omitted.
The first magnetic flux converging portion 41 and the second magnetic flux converging portion 42 of the magnetic flux converging member 40 are not limited to being an integrally formed structure. For example, the first magnetic flux converging portion 41 and the second magnetic flux converging portion 42 can also be in a configuration in which the first magnetic flux converging portion 41 and the second magnetic flux converging portion 42 are formed of different materials and in contact with each other. Moreover, the second magnetic flux converging portion 42 can also be configured to be non-continuous with the first magnetic flux converging portion 41, that is, the first magnetic flux converging portion 41 is configured to be separated from the second magnetic flux converging portion 42. In this case, the first magnetic flux converging portion 41 is arranged near the second magnetic flux converging portion 42 in a way that magnetic flux is guided from the side of the second magnetic flux converging portion 42 to the side of the first magnetic flux converging portion 41. The above also applies to the second magnetic flux converging portion 420 of the second magnetic flux converging member 400.
In the opposing direction of the magnetic flux converging member 40, the position for providing the second magnetic flux converging portion 42 can also be modified. For example, the second magnetic flux converging portion 42 can also be provided on a midpoint between the end 41E1 of the first magnetic flux converging portion 41 on the side of the magnetic detection element 20 and the end 41E2 located on an opposite side. Regarding the second embodiment and the third embodiment, the position of the second magnetic flux converging portion 420 can also be modified similarly.
Regarding the first magnetic flux converging portion 41 of the first embodiment and the third embodiment, the support portion 43 can be omitted and the first magnetic flux converging portion 41 in a hollow shape can be provided. In this case, the magnetic film 44 is formed by a rigid magnetic material capable of maintaining a shape. The first magnetic flux converging portion 410 of the second embodiment and the third embodiment can be similarly set to be a hollow shape.
Regarding the first magnetic flux converging portion 41 of the first embodiment and the third embodiment, the first magnetic flux converging portion 41 entirely formed by a solid magnetic member can also be used in substitution for a configuration including the support portion 43 and the magnetic film 44. The first magnetic flux converging portion 410 of the second embodiment and the third embodiment can also be configured to be a solid magnetic member.
Regarding the third embodiment, either of the second magnetic flux converging portion 42 of the first magnetic flux converging member 40 and the second magnetic flux converging portion 42 of the second magnetic flux converging member 400 can be omitted.
The terms such as “on” used in the present application also includes meanings of both “over” and “above”, unless otherwise specified in the context. Thus, an expression such as “a configuration A formed on a configuration B” means that, in some embodiments, the configuration A can be in contact with the configuration B and be directly disposed on the configuration B, while in other embodiments, the configuration A can be disposed over or above the configuration B without coming into contact with the configuration B. That is to say, the expression “on” does not eliminate a structure having another component formed between the configuration A and configuration B.

The Z-direction used in the present disclosure is not necessarily a vertical direction, and is not necessarily completely consistent with the vertical direction. Thus, various structures associated with the present disclosure do not limit “up/top” and “down/bottom” of the Z-direction given in the description to be “up” and “down” of the vertical direction. For example, the X-axis direction can be the vertical direction, or the Y-axis direction can be the vertical direction.

The terms “first”, “second” and “third” of the present disclosure are for distinguishing targets, and are not intended for sorting an order of the targets.

### NOTES

The technical concepts encompassed by the present disclosure are recorded in the description below. Moreover, to help better understand rather than intended as limitations, the constituting elements described in the notes are given with the same reference numerals or symbols of the corresponding constituting elements in the embodiments. The numerals or symbols are used as examples for understanding purposes, and the constituting elements described in the notes are not to be limited to the constituting elements indicated by the numerals or symbols.

### [Note 1]

A magnetic detection device (10, 110, 120), comprising:
a magnetic detection element (20); and
a magnetic flux converging member (40, 400), disposed opposite to the magnetic detection element (20) and configured to guide magnetic flux to the magnetic detection element (20), wherein the magnetic flux converging member (40, 400) includes:
   a first magnetic flux converging portion (41, 410), extending in a direction and facing the magnetic flux converging member (40, 400) with respect to the magnetic detection element (20), and
   a second magnetic flux converging portion (42, 420), in a plan view seen from an opposing direction, protruding more laterally than the first magnetic flux converging portion (41, 410), wherein
the magnetic flux converging member (40, 400) guides magnetic flux passing through the second magnetic flux converging portion (42, 420) to the magnetic detection element (20) through the first magnetic flux converging portion (41, 410

### [Note 2]

The magnetic detection device (10, 110, 120) according to note 1, wherein
the second magnetic flux converging portion (42, 420) includes a base portion (42A, 420A) connected continuously with the first magnetic flux converging portion (41, 410), and a tip portion (42B, 420B) located at an outer periphery of the second magnetic flux converging portion (42, 420) in the plan view, and
at least a part of the tip portion (42B, 420B) is located more laterally than the first magnetic flux converging portion (41, 410) in the plan view.

### [Note 3]

The magnetic detection device (10, 110, 120) according to note 2, wherein the base portion (42A, 420A) of the second magnetic flux converging portion (42, 420) is an end of the first magnetic flux converging portion (41, 410) in the opposing direction and connected continuously with an end (41E2) located on an opposite side of an end of the magnetic detection element (41, 410).

### [Note 4]

The magnetic detection device (10, 110, 120) according to note 3, wherein the magnetic detection element (20) includes a sensing unit (21) for detecting magnetic flux, and the at least part of the tip portion (42B, 420B) of the second magnetic flux converging portion (42, 420) protrudes from the sensing unit (21) in the plan view.

### [Note 5]

The magnetic detection device (10, 110, 120) according to any one of notes 1 to 3, wherein the second magnetic flux converging portion (42, 420) has a rectangular shape in the plan view.

### [Note 6]

The magnetic detection device (10, 110, 120) according to note 2, wherein
the second magnetic flux converging portion (42, 420) has a rectangular shape in the plan view;
the tip portion (42B, 420B) of the second magnetic flux converging portion (42, 420) has a first side (42C1), a second side (42C2), a third side (42C3) and a fourth side (42C4) located on each of four sides of the rectangular shape; and
at least one of distances (LAa, LAb, LAc, L4d) from the base portion (42A, 420A) of the second magnetic flux converging portion (42, 420) to the first side (42C1), the second side (42C2), the third side (42C3) and the fourth side (42C4) is between about 0.1 μm and about 250 μm.

### [Note 7]

The magnetic detection device (10, 110, 120) according to any one of notes 1 to 6, wherein the first magnetic flux converging portion (41, 410) includes:
a support portion (43), having a cylindrical shape and extending toward the magnetic detection element (20); and
a magnetic film (44), coated on a surface of the support portion (43).

### [Note 8]

The magnetic detection device (10, 110, 120) according to any one of notes 1 to 7, wherein the first magnetic flux converging portion (41, 410) has a side surface (41B, 410B) continuous with the second magnetic flux converging portion (42, 420), and the side surface (41B, 410B) includes an upright surface in parallel to the opposing direction.

### [Note 9]

The magnetic detection device (10, 110, 120) according to note 8, wherein the first magnetic flux converging portion (41, 410) has a rectangular prism shape with the opposing direction as a height direction.

### [Note 10]

The magnetic detection device (10, 110, 120) according to any one of notes 1 to 9, wherein in the opposing direction, a length of the first magnetic flux converging portion (41, 410) is between about 0.2 μm and about 200 μm.

### [Note 11]

The magnetic detection device (10, 110, 120) according to any one of notes 1 to 10, wherein the magnetic detection element (20) includes a sensing unit (21) for detecting magnetic flux, the sensing unit (21) is separated from the first magnetic flux converging portion (41, 410) of the magnetic flux converging member (40, 400) in the opposing direction, and a separation distance (L3, L3A) between the sensing unit (21) and the first magnetic flux converging portion (41, 410) is between about 0.1 μm and about 100 μm.

### [Note 12]

The magnetic detection device (10, 110, 120) according to any one of notes 1 to 11, wherein the magnetic detection element (20) includes a sensing unit (21) for detecting magnetic flux; and at least a portion of the sensing unit (21) protrudes from the first magnetic flux converging portion (41, 410) of the magnetic flux converging member (40, 400) in the plan view.

### [Note 13]

The magnetic detection device (10, 120) according to any one of notes 1 to 12, further comprising:
a substrate (30) having an opposing surface (30A) facing the magnetic detection element (20), wherein
the magnetic flux converging member (40) is disposed between the magnetic detection element (20) and the substrate (30).

### [Note 14]

The magnetic detection device (110) according to any one of notes 1 to 12, wherein the magnetic detection element (20) has a first surface as a mounting surface (20A) upon mounting of the magnetic detection device (110), and a second surface (20B) located on an opposite side of the first surface (20A); and the magnetic flux converging member (400) is disposed on the second surface (20B) of the magnetic detection element (20).

### [Note 15]

The magnetic detection device (120) according to any one of notes 1 to 12, further comprising:
a substrate (30) having an opposing surface (30A) facing the magnetic detection element (20), wherein
the magnetic detection element (20) has a first surface (20A) facing the substrate (30) and a second surface (20B) located on an opposite side of the first surface (20A); and
the magnetic flux converging member (40, 400) includes:
   a first magnetic flux converging member (40), disposed between the first surface (20A) of the magnetic detection element (20) and the opposing surface (30A) of the substrate (30); and
   a second magnetic flux converging member (400), disposed on the second surface (20B) of the magnetic detection element (20).

1. A magnetic detection device, comprising:
a magnetic detection element; and
a magnetic flux converging member, disposed opposite to the magnetic detection element and configured to guide magnetic flux to the magnetic detection element, wherein the magnetic flux converging member includes:
a first magnetic flux converging portion, extending in a direction and facing the magnetic flux converging member with respect to the magnetic detection element, and
a second magnetic flux converging portion, in a plan view seen from an opposing direction, protruding more laterally than the first magnetic flux converging portion, wherein
the magnetic flux converging member guides magnetic flux passing through the second magnetic flux converging portion to the magnetic detection element via the first magnetic flux converging portion.

2. The magnetic detection device of claim 1, wherein
the second magnetic flux converging portion includes a base portion connected continuously with the first magnetic flux converging portion, and a tip portion located at an outer periphery of the second magnetic flux converging portion in the plan view, and
at least a part of the tip portion is located more laterally than the first magnetic flux converging portion in the plan view.

3. The magnetic detection device of claim 2, wherein the base portion of the second magnetic flux converging portion is an end of the first magnetic flux converging portion in the opposing direction and connected continuously with an end located on an opposite side of an end of the magnetic detection element.

4. The magnetic detection device of claim 2, wherein the magnetic detection element includes a sensing unit for detecting magnetic flux, and the at least part of the tip portion of the second magnetic flux converging portion protrudes from the sensing unit in the plan view.

5. The magnetic detection device of claim 1, wherein the second magnetic flux converging portion has a rectangular shape in the plan view.

6. The magnetic detection device of claim 2, wherein
the second magnetic flux converging portion has a rectangular shape in the plan view,
the tip portion of the second magnetic flux converging portion has a first side, a second side, a third side and a fourth side located on each of four sides of the rectangular shape, and
at least one of distances from the base portion of the second magnetic flux converging portion to the first side, the second side, the third side and the fourth side is between about 0.1 micrometer (μm) and about 250 μm.

7. The magnetic detection device of claim 1, wherein the first magnetic flux converging portion includes:
a support portion, having cylindrical shape and extending toward the magnetic detection element; and
a magnetic film, coated on a surface of the support portion.

8. The magnetic detection device of claim 1, wherein
the first magnetic flux converging portion has a side surface continuous with the second magnetic flux converging portion, and
the side surface includes an upright surface in parallel to the opposing direction.

9. The magnetic detection device of claim 8, wherein the first magnetic flux converging portion has a rectangular prism shape with the opposing direction as a height direction.

10. The magnetic detection device of claim 1, wherein in the opposing direction, a length of the first magnetic flux converging portion is between about 0.2 μm and about 200 μm.

11. The magnetic detection device of claim 1, wherein
the magnetic detection element includes a sensing unit for detecting magnetic flux,
the sensing unit is separated from the first magnetic flux converging portion of the magnetic flux converging member in the opposing direction, and
a separation distance between the sensing unit and the first magnetic flux converging portion is between about 0.1 μm and about 100 μm.

12. The magnetic detection device of claim 1, wherein
the magnetic detection element includes a sensing unit for detecting magnetic flux, and
at least a portion of the sensing unit protrudes from the first magnetic flux converging portion of the magnetic flux converging member in the plan view.

13. The magnetic detection device of claim 1, further comprising a substrate having an opposing surface facing the magnetic detection element, wherein the magnetic flux converging member is disposed between the magnetic detection element and the substrate.

14. The magnetic detection device of claim 2, further comprising a substrate having an opposing surface facing the magnetic detection element, wherein the magnetic flux converging member is disposed between the magnetic detection element and the substrate.

15. The magnetic detection device of claim 5, further comprising a substrate having an opposing surface facing the magnetic detection element, wherein the magnetic flux converging member is disposed between the magnetic detection element and the substrate.

16. The magnetic detection device of claim 1, wherein
the magnetic detection element has a first surface as a mounting surface upon mounting of the magnetic detection device, and a second surface located on an opposite side of the first surface, and
the magnetic flux converging member is disposed on the second surface of the magnetic detection element.

17. The magnetic detection device of claim 2, wherein
the magnetic detection element has a first surface as a mounting surface upon mounting of the magnetic detection device, and a second surface located on an opposite side of the first surface, and
the magnetic flux converging member is disposed on the second surface of the magnetic detection element.

18. The magnetic detection device of claim 5, wherein
the magnetic detection element has a first surface as a mounting surface upon mounting of the magnetic detection device, and a second surface located on an opposite side of the first surface, and
the magnetic flux converging member is disposed on the second surface of the magnetic detection element.

19. The magnetic detection device of claim 1, further comprising a substrate having an opposing surface facing the magnetic detection element, wherein
the magnetic detection element has a first surface facing the substrate and a second surface located on an opposite side of the first surface, and
the magnetic flux converging member includes:
a first magnetic flux converging member, disposed between the first surface of the magnetic detection element and the opposing surface of the substrate; and
a second magnetic flux converging member, disposed on the second surface of the magnetic detection element.

20. The magnetic detection device of claim 2, further comprising a substrate having an opposing surface facing the magnetic detection element, wherein
the magnetic detection element has a first surface facing the substrate and a second surface located on an opposite side of the first surface, and
the magnetic flux converging member includes:
a first magnetic flux converging member, disposed between the first surface of the magnetic detection element and the opposing surface of the substrate; and
a second magnetic flux converging member, disposed on the second surface of the magnetic detection element.
